(19) United States
(12) Patent Application Publication
(10) Pub. No.: US 2011/0117268 A1
(43) Pub. Date: May 19, 2011

(54) CONSUMABLE MATERIALS HAVING ENCODED MARKINGS FOR USE WITH DIRECT DIGITAL MANUFACTURING SYSTEMS

(75) Inventors: J. Samuel Batchelder, Somers, NY (US); Michael Bosveld, Bloomington, MN (US)

(73) Assignee: STRATASYS, INC., Eden Prairie, MN (US)

(21) Appl. No.: 12/622,042

(22) Filed: Nov. 19, 2009

(51) Int. Cl. C23C 16/52; B32B 3/00; B32B 5/02; B29C 35/08

(52) U.S. Cl. 427/8; 428/195.1; 428/375; 264/400

(57) ABSTRACT

A consumable material comprising an exterior surface having encoded markings that are configured to be read by at least one sensor of a direct digital manufacturing system, where the consumable material is configured to be consumed in the direct digital manufacturing system to build at least a portion of a three-dimensional model.

### CROSS-REFERENCE TO RELATED APPLICATION(S)

Reference is hereby made to U.S. Provisional Patent Application No. ______, filed on even date, and entitled “Optical Sensor Assembly For Use With Consumable Materials Having Encoded Markings” (attorney docket no. S697.12-0155), the disclosure of which is incorporated by reference in its entirety.

### BACKGROUND

The present disclosure relates to direct digital manufacturing systems for building three-dimensional (3D) models. In particular, the present disclosure relates to consumable materials, such as modeling and support materials, for use in direct digital manufacturing systems, such as extrusion-based digital manufacturing systems.

An extrusion-based digital manufacturing system (e.g., fused deposition modeling systems developed by Stratasys, Inc., Eden Prairie, Minn.) is used to build a 3D model from a digital representation of the 3D model in a layer-by-layer manner by extruding a flowable consumable modeling material. The modeling material is extruded through an extrusion tip carried by an extrusion head, and is deposited as a sequence of roads on a substrate in an x-y plane. The extruded modeling material fuses to previously deposited modeling material, and solidifies upon a drop in temperature. The position of the extrusion head relative to the substrate is then incremented along a z-axis (perpendicular to the x-y plane), and the process is then repeated to form a 3D model resembling the digital representation.

Movement of the extrusion head with respect to the substrate is performed under computer control, in accordance with build data that represents the 3D model. The build data is obtained by initially slicing the digital representation of the 3D model into multiple horizontally sliced layers. Then, for each sliced layer, the host computer generates a build path for depositing roads of modeling material to form the 3D model.

In fabricating 3D models by depositing layers of a modeling material, supporting layers or structures are typically built underneath overhanging portions or in cavities of objects under construction, which are not supported by the modeling material itself. A support structure may be built utilizing the same deposition techniques by which the modeling material is deposited. The host computer generates additional geometry acting as a support structure for the overhanging or free-space segments of the 3D model being formed. Consumable support material is then deposited from a second nozzle pursuant to the generated geometry during the build process. The support material adheres to the modeling material during fabrication, and is removable from the completed 3D model when the build process is complete.

### SUMMARY

An aspect of the present disclosure is directed to a consumable material for use in a direct digital manufacturing system. The consumable material includes an exterior surface having at least one encoded marking that is configured to be read by at least one sensor of the direct digital manufacturing system. The consumable material is configured to be consumed in the direct digital manufacturing system to build at least a portion of a three-dimensional model.

Another aspect of the present disclosure is directed to a method of manufacturing a marked consumable material for use in a direct digital manufacturing system. The method includes providing a consumable material precursor having an exterior surface, where the consumable material precursor is formed from an extrudable material. The method also includes forming at least one encoded marking at the exterior surface of the consumable material precursor that is configured to be read by at least one sensor in the direct digital manufacturing system. The marked consumable material is configured to be consumed in the direct digital manufacturing system to build at least a portion of a three-dimensional model.

Another aspect of the present disclosure is directed to a method for building a three-dimensional model with a direct digital manufacturing system. The method includes feeding a marked consumable material to the direct digital manufacturing system, where the marked consumable material includes an exterior surface having encoded markings. The method also includes reading at least a portion of the encoded markings while feeding the marked consumable material to the direct digital manufacturing system, melting the marked consumable material to at least an extrudable state in the direct digital manufacturing system, and depositing the melted material from a deposition head of the direct digital manufacturing system to form the three-dimensional model in a layer-by-layer manner.

### BRIEF DESCRIPTION OF THE DRAWINGS

FIG. 1 is a front view of an extrusion-based digital manufacturing system for building 3D models and support structures from marked consumable materials having encoded markings.

FIG. 2 is a perspective view of a segment of a marked cylindrical filament, which is an example of a marked consumable material for use in the extrusion-based digital manufacturing system.

FIG. 3 is a perspective view of a segment of a marked non-cylindrical filament, which is an additional example of a marked consumable material for use in the extrusion-based digital manufacturing system.

FIG. 4 is a perspective view of a marked slug or wafer, which is an additional example of a marked consumable material for use in the extrusion-based digital manufacturing system.

FIG. 5 is a flow diagram of a method for manufacturing marked consumable materials.

FIG. 6 is a schematic illustration of a laser marking system configured to form encoded markings in consumable materials.

### DETAILED DESCRIPTION

The present disclosure is directed to marked consumable materials for use in direct digital manufacturing systems, such as extrusion-based digital manufacturing systems. The marked consumable materials include encoded markings that may contain a variety of information, such as information relating to properties of the marked consumable materials (e.g., physical and compositional properties) and information relating to parameters for operating the digital manufacturing systems (e.g., extrusion parameters).

The present disclosure is also directed sensor assemblies configured to read the encoded markings from successive portions of the marked consumable materials as the marked consumable materials are fed to the direct digital manufacturing systems. As discussed below, the sensor assemblies may transmit the information read from the encoded markings to one or more control components of the direct digital manufacturing systems. This allows the direct digital manufacturing systems to use the information in the encoded markings for a variety of different purposes, such as for building 3D models and/or support structures.

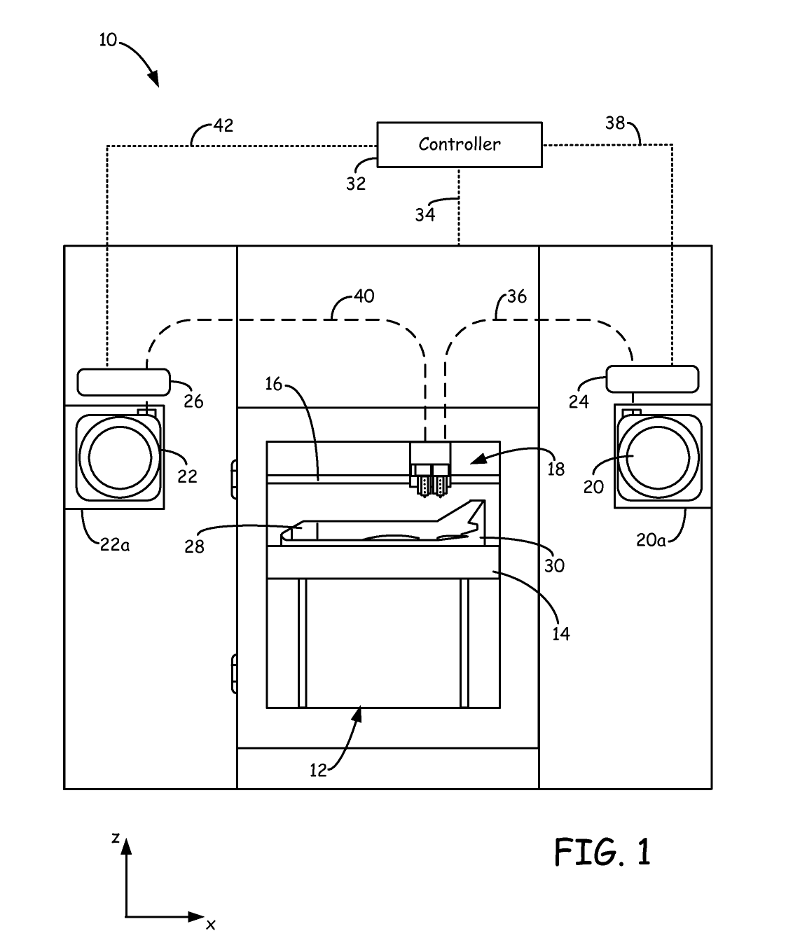

FIG. 1 is a front view of system 10, which is a direct digital manufacturing system, such as an extrusion-based digital manufacturing system. Suitable extrusion-based digital manufacturing systems for system 10 include fused deposition modeling systems developed by Stratasys, Inc., Eden Prairie, Minn. As shown, system 10 includes build chamber 12, platen 14, gantry 16, extrusion head 18, supply sources 20 and 22, and sensor assemblies 24 and 26, where sensor assemblies 24 and 26 are configured to read information from marked consumable materials (not shown in FIG. 1) provided in supply sources 20 and 22.

Build chamber 12 is an enclosed environment that contains platen 14, gantry 16, and extrusion head 18 for building a 3D model (referred to as 3D model 28) and a corresponding support structure (referred to as support structure 30). Build chamber 12 is desirably heated to reduce the rate at which the modeling and support materials solidify after being extruded and deposited.

Platen 14 is a platform on which 3D model 28 and support structure 30 are built, and moves along a vertical z-axis based on signals provided from a computer-operated controller (referred to as controller 32). As shown, controller 32 may communicate with build chamber 12, platen 14, gantry 16, and extrusion head 18 over communication line 34. While illustrated as a single signal line, communication line 34 may include one or more signal lines for allowing controller 32 to communicate with various components of system 10, such as build chamber 12, platen 14, gantry 16, and extrusion head 18.

Gantry 16 is a guide rail system configured to move extrusion head 18 in a horizontal x-y plane within build chamber 12 based on signals provided from controller 32 (via communication line 34). The horizontal x-y plane is a plane defined by an x-axis and a y-axis (not shown in FIG. 1), where the x-axis, the y-axis, and the z-axis are orthogonal to each other. In an alternative embodiment, platen 14 may be configured to move in the horizontal x-y plane within build chamber 12, and extrusion head 18 may be configured to move along the z-axis. Other similar arrangements may also be used such that one or both of platen 14 and extrusion head 18 are moveable relative to each other.

Extrusion head 18 is supported by gantry 16 for building 3D model 28 and support structure 30 on platen 14 in a layer-by-layer manner, based on signals provided from controller 32. Extrusion head 18 includes a pair of liquefiers (not shown in FIG. 1) configured to receive and melt successive portions of the marked consumable materials. Examples of suitable extrusion heads for extrusion head 18 include those disclosed in LaBossiere, et al., U.S. Patent Application Publication Nos. 2007/0003656 and 2007/00228590; Leavitt, U.S. Patent Application Publication No. 2009/0035405; and Batchelder et al., U.S. Provisional Patent Application Nos. 61/247,067; 61/247,068; and 61/247,078. Alternatively, system 10 may include one or more two-stage pump assemblies, such as those disclosed in Batchelder et al., U.S. Pat. No. 5,764,521; and Skubic et al., U.S. Patent Application Publication No. 2008/0213419. Furthermore, system 10 may include a plurality of extrusion heads 18 for depositing modeling and/or support materials.

Supply sources 20 and 22 are devices retaining supplies of the marked consumable materials, and may be respectively loaded into bays 20a and 22a of system 10. In the shown embodiment, supply source 20 retains a supply of a marked modeling material and supply source 22 retains a supply of a marked support material. System 10 may also include additional drive mechanisms (not shown) configured to assist in feeding the marked consumable materials from supply sources 20 and 22 to extrusion head 18.

In some embodiments, the marked consumable materials may be provided to system 10 as filaments having marked exterior surfaces (not shown in FIG. 1), such as marked cylindrical filaments and/or marked non-cylindrical filaments, as discussed below. In these embodiments, suitable assemblies (e.g., spooled containers) for supply sources 20 and 22 include those disclosed in Swanson et al., U.S. Pat. No. 6,923,634; Comb et al., U.S. Pat. No. 7,122,246; Taatjes et al, U.S. patent application Ser. Nos. 12/255,808 and 12/255,811; and Swanson, U.S. Provisional Patent Application No. 61/010,399 and International Publication No. WO2009/088995.

In alternative embodiments, the marked consumable materials may be provided to system 10 as marked slugs or wafers, as further discussed below. In these embodiments, suitable assemblies for supply sources 20 and 22 include those disclosed in Batchelder et al., U.S. Pat. No. 5,764,521.

Sensor assemblies 24 and 26 are configured to read the encoded markings of the marked consumable materials as the marked consumable materials are fed to extrusion head 18. Sensor assembly 24 may be retained at any suitable location between supply source 20 and extrusion head 18. Similarly, sensor assembly 26 may be retained at any suitable location between supply source 22 and extrusion head 18. In the shown embodiment, sensor assemblies 24 and 26 are retained within system 10 adjacent to supply sources 20 and 22, respectively. In an alternative embodiment, one or both of sensor assemblies 24 and 26 may be retained by gantry 16 with extrusion head 18, thereby moving sensor assemblies 24 and 26 with extrusion head 18.

In an additional alternative embodiment, as disclosed in U.S. Provisional Patent Application No. ______, filed on even date, and entitled “Optical Sensor Assembly For Use With Consumable Materials Having Encoded Markings” (attorney docket no. S697.12-0155), sensor assembly 24 may each include a first subassembly retained within system 10 at bay 20a, and a second subassembly retained within supply source 20. In this embodiment, the first and second subassemblies may engaged with each other when supply source 20 is loaded to bay 20a of system 10. Sensor assembly 26 may also include the same arrangement for bay 22a and supply source 22.

The marked modeling material may be provided to extrusion head 18 from supply source 20 through pathway 36, where pathway 36 may include a guide tube (not shown) for guiding the marked modeling material to extrusion head 18. In the shown embodiment, pathway 36 extends through sensor assembly 24, thereby allowing sensor assembly 24 to read the encoded information from the marked modeling material. As further shown, sensor assembly 24 may communicate with controller 32 and/or any other control component of system 10 (e.g., a host computer system for system 10, not shown) over communication line 38. While illustrated as a single signal line, communication line 38 may include one or more signal lines for allowing sensor assembly 24 to communicate with one or more control components of system 10 (e.g., controller 32).

Similarly, the marked support material may be provided to extrusion head 18 from supply source 22 through pathway 40, where pathway 40 may also include a guide tube (not shown) for guiding the marked support material to extrusion head 18. In the shown embodiment, pathway 40 extends through sensor assembly 26, thereby allowing sensor assembly 26 to read the encoded information from the marked support material. As further shown, sensor assembly 26 may communicate with controller 32 and/or any other control component of system 10 (e.g., the host computer system for system 10) over communication line 42. While illustrated as a single signal line, communication line 42 may include one or more signal lines for allowing sensor assembly 26 to communicate with one or more control components of system 10 (e.g., controller 32).

During a build operation, the marked consumable materials may be fed to extrusion head 18 through pathways 36 and 40. Sensor assemblies 24 and 26 may read the encoded markings of the marked consumable materials as successive portions of the marked consumable materials pass through pathways 36 and 40. Information retained in the encoded markings may then be transmitted to controller 32 over communication lines 38 and 42, thereby allowing controller 32 to use the received information to assist in building 3D model 28 and/or support structure 30. For example, controller 32 may modify the extrusion parameters transmitted to extrusion head 18, allowing the thermal properties of extrusion head 18 to be adjusted based on the received information. In one embodiment, the thermal properties of extrusion head 18 may be adjusted based on received information relating to the cross sectional areas of successive portions of the consumable materials.

Additionally, the received information may relate to the amount of the marked consumable materials remaining in supply source 20 or 22. This is beneficial for informing a user of system 10 how long the current supply of the marked consumable material will last before the user needs to load a new supply source to system 10. This information is particularly suitable for allowing the user to know if the build operation will end during a time period when the user may not necessarily be present to load a new supply source to system 10 (e.g., during overnight and/or weekend periods).

Furthermore, the received information may relate to the marked consumable material itself, such as the material type (e.g., modeling and support materials), material composition, and/or the material color. Sensor assemblies 24 and 26 may read these types of information from the marked consumable materials to confirm that the proper material was loaded to system 10, thereby reducing the risk of accidentally running system 10 with an incorrect material. For example, sensor assembly 24 may read information from the marked consumable material being fed from supply source 20, and controller 32 may confirm that the material being fed through pathway 36 is an intended modeling material, rather than a support material.

Combinations of the read information may also be used to assist in building 3D model 28 and/or support structure 30. For example, in embodiments in which bays 20a and 22a may each accept supply sources of modeling and support materials, the user may load supply source 20 of the marked modeling material into either bay 20a or bay 22a, and after the corresponding sensor assembly 24 or 26 reads the information from the marked consumable material, controller 32 may identify that the material is a modeling material for building 3D model 28 and adjust the extrusion parameters and feed rates accordingly. A similar arrangement may be accomplished with the marked support material in supply source 22. This prevents the user from having to load a particular supply source into a particular bay of system 10.

As the marked consumable materials are fed to extrusion head 18, gantry 16 may move extrusion head 18 around in the horizontal x-y plane within build chamber 12. Extrusion head 18 thermally melts the successive portions of the received marked modeling material, thereby allowing the molten modeling material to be extruded to build 3D model 28. Similarly, extrusion head 18 thermally melts the successive portions of the marked support material, thereby allowing the molten support material to be extruded to build support structure 30. The upstream, unmelted portions of the marked consumable materials may each function as a piston with a viscosity-pump action to extrude the molten material out of the respective liquefiers of extrusion head 18.

The extruded modeling and support materials are deposited onto platen 14 to build 3D model 28 and support structure 30 using a layer-based additive technique. Support structure 30 is desirably deposited to provide vertical support along the z-axis for overhanging regions of the layers of 3D model 28. After the build operation is complete, the resulting 3D model 28/support structure 30 may be removed from build chamber 12, and support structure 30 may be removed from 3D model 28. As used herein, the term “three-dimensional model” is intended to encompass any object built with a direct digital manufacturing system, and includes 3D models built from modeling materials (e.g., 3D model 28) as well a support structures built from support materials (e.g., support structure 30).

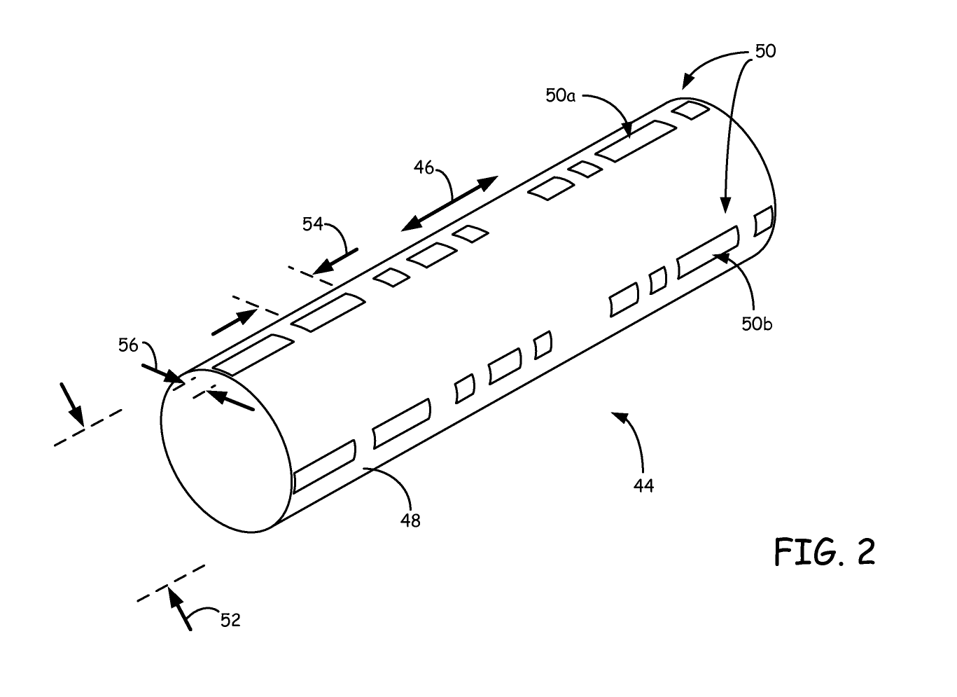

FIG. 2 illustrates a segment of filament 44, which is an example of a suitable marked consumable material of the present disclosure for use as a marked modeling material and/or a marked support material with system 10 (shown in FIG. 1). As shown in FIG. 2, filament 44 is a marked cylindrical filament having length 46, where length 46 is a continuous length that may vary depending on the amount of filament 44 remaining in supply source 20 or 22. While only a segment of filament 44 is illustrated in FIG. 2, it is understood that length 46 of filament 44 may extend for a substantial distance (e.g., greater than 25 meters).

Filament 44 also includes exterior surface 48 extending along length 46 and encoded markings 50, where encoded markings 50 are located at exterior surface 48 along at least a portion of length 46. In one embodiment, encoded markings 50 extend substantially along the entire length 46. Filament 44 also has a surface diameter (referred to as surface diameter 52) at a non-marked location that is desirably configured to allow filament 44 to mate with a liquefier of extrusion head 18 without undue friction. Examples of suitable average diameters for surface diameter 52 range from about 0.8 millimeters (about 0.03 inches) to about 2.5 millimeters (about 0.10 inches), with particularly suitable average diameters ranging from about 1.0 millimeter (about 0.04 inches) to about 2.3 millimeters (about 0.09 inches), and with even more particularly suitable average diameters ranging from about 1.3 millimeters (about 0.05 inches) to about 2.0 millimeters (about 0.08 inches).

In the shown embodiment, encoded markings 50 are trench-based markings in exterior surface 48 (e.g., via laser ablation). However, as discussed below, encoded markings 50 may alternatively be form on filament 44 using a variety of different marking techniques. For example, encoded markings may be formed as coatings over exterior surface 48 via one or more coating processes (e.g., jetting and evaporation processes).

Encoded markings 50 include encoded information, which may be read by sensor assembly 24 or 26 as successive portions of filament 44 pass through pathway 36 or 40 of system 10. As discussed above, the read information may then be transmitted to controller 32 over communication line 38 or 42, thereby allowing controller 32 to use the received information to assist in building 3D model 28 and/or support structure 30.

Encoded markings 50 may extend in multiple linear paths along length 46 (referred to as paths 50a and 50b), as shown. In this embodiment, encoded markings 50 may also include a third linear path (referred to as path 50c, not shown) such that paths 50a, 50b, and 50c are each separated by angles of about 120 degrees. This arrangement is beneficial for allowing sensor assembly 24 or 26 to read at least one of paths 50a, 50b, and 50c regardless of the axial orientation of filament 44 as successive portions of filament 44 pass through the given sensor assembly 24 or 26. In alternative embodiments, filament 44 may include fewer or additional paths of encoded markings 50 such that filament 44 includes at least one path of encoded markings 50 (e.g., paths 50a, 50b, and 50c). In additional alternative embodiments, one or more of the paths (e.g., paths 50a, 50b, and 50c) may extend along length 46 in a non-linear manner (e.g., S-curves and spiral arrangements).

Encoded markings 50 may include a variety of different information, such as information relating to filament 44 and/or system 10. Examples of suitable types of information that may be included in encoded markings 50 include local filament cross-sections (e.g., diameters and root-mean-square variations), local and global filament extrusion parameters, length of filament 44 remaining in supply source 20 or 22, measurements of local filament fingerprint characteristics, material type (e.g., modeling and support materials), material composition, material color, manufacturing information for filament 44 (e.g., manufacturing dates, manufacturing locations, and lot numbers), product codes, material origin information, software and firmware updates for system 10, and combinations thereof.

In addition, encoded markings 50 may also include media-based information, such as operating and use instructions, artistic works (e.g., textual, video, and audio information), and the like. In these embodiments, system 10 may include capabilities for playing the encoded media, such as textual and/or graphical information that may be displayed for a user of system 10 to read, and/or audio information that may be played for a user of system 10 to hear. The amount of data per unit length along length 46 of filament 44 may vary depending on the particular marking technique used, the encoding scheme used, the dimensions of encoded markings 50, the number of encoded markings per unit length along length 46, and the like.

The dimensions and geometries of each mark of encoded markings 50 may vary depending on the encoding scheme and the marking technique used. In the current example in which encoded markings 50 are formed as trenches in exterior surface 48 (e.g., via laser ablation), encoded markings 50 desirably have small dimensions relative to the overall dimensions of filament 44 to minimize or otherwise reduce their impact on the diameter of filament 44. Additionally, as shown in the current embodiment, the trenches of encoded markings 50 have axial lengths (e.g., axial length 54) that vary to provide patterns based on the encoding scheme used. In alternative embodiments one or more of the radial widths of the marks (referred to as widths 56) and/or the depths of the marks may additionally or alternatively be varied to provide patterns based on the encoding scheme used.

Suitable average dimensions for width 56 range from about 51 micrometers (about 2 mils) to about 510 micrometers (about 20 mils), with particularly suitable average dimensions ranging from about 130 micrometers (about 5 mils) to about 250 micrometers (about 10 mils). Suitable dimensions for the axial lengths along length 46 (e.g., axial length 54) range from about 130 micrometers (about 5 mils) to about 5,100 micrometers (about 200 mils), with particularly suitable axial lengths ranging from about 1,300 micrometers (about 50 mils) to about 3,800 micrometers (about 150 mils).

Furthermore, suitable average depths of each mark of encoded markings 50 from exterior surface 48 range from about 1.3 micrometers (about 0.05 mils) to about 51 micrometers (about 2 mils), with particularly suitable average depths ranging from about 13 micrometers (about 0.5 mil) to about 38 micrometers (about 1.5 mils). As discussed below, the edges of the trench marks are suitable regions for scattering light in a darkfield illumination, which may allow an optical sensor assembly to read encoded markings 50 based on the patterns of the scattered light. In alternative embodiments, the encoded markings of filament 44 may be two-dimensional markings (e.g., coatings) rather than the three-dimensional geometry of encoded markings 50.

Filament 44 may be manufactured from a variety of extrudable modeling and support materials for respectively building 3D model 28 and support structure 30. Suitable modeling materials for filament 44 include polymeric and metallic materials. In some embodiments, suitable modeling materials include materials having amorphous properties, such as thermoplastic materials, amorphous metallic materials, and combinations thereof. Examples of suitable thermoplastic materials for filament 44 include acrylonitrile-butadiene-styrene (ABS) copolymers, polycarbonates, polysulfones, polyethersulfones, polyphenylsulfones, polyetherimides, amorphous polyamides, modified variations thereof (e.g., ABS-M30 copolymers), polystyrene, and blends thereof. Examples of suitable amorphous metallic materials include those disclosed in Batchelder, U.S. patent application Ser. No. 12/417,740.

Suitable support materials for filament 44 include polymeric materials. In some embodiments, suitable support materials include materials having amorphous properties (e.g., thermoplastic materials) and that are desirably removable from the corresponding modeling materials after 3D model 28 and support structure 30 are built. Examples of suitable support materials for filament 44 include water-soluble support materials commercially available under the trade designations “WATERWORKS” and “SOLUBLE SUPPORTS” from Stratasys, Inc., Eden Prairie, Minn.; break-away support materials commercially available under the trade designation “BASS” from Stratasys, Inc., Eden Prairie, Minn., and those disclosed in Crump et al., U.S. Pat. No. 5,503,785; Lombardi et al., U.S. Pat. Nos. 6,070,107 and 6,228,923; Priedeman et al., U.S. Pat. No. 6,790,403; and Hopkins et al., U.S. patent application Ser. No. 12/508,725.

The composition of filament 44 may also include additional additives, such as plasticizers, rheology modifiers, inert fillers, colorants, stabilizers, and combinations thereof. Examples of suitable additional plasticizers for use in the support material include dialkyl phthalates, cycloalkyl phthalates, benzyl and aryl phthalates, alkoxy phthalates, alkyl/aryl phosphates, polyglycol esters, adipate esters, citrate esters, esters of glycerin, and combinations thereof. Examples of suitable inert fillers include calcium carbonate, magnesium carbonate, glass spheres, graphite, carbon black, carbon fiber, glass fiber, talc, wollastonite, mica, alumina, silica, kaolin, silicon carbide, composite materials (e.g., spherical and filamentary composite materials), and combinations thereof. In embodiments in which the composition includes additional additives, examples of suitable combined concentrations of the additional additives in the composition range from about 1% by weight to about 10% by weight, with particularly suitable concentrations ranging from about 1% by weight to about 5% by weight, based on the entire weight of the composition.

Filament 44 also desirably exhibits physical properties that allow filament 44 to be used as a consumable material in system 10. For example, filament 44 is desirably flexible along length 46 to allow filament 44 to be retained in supply sources 20 and 22 (e.g., wound on spools) and to be fed through system 10 (e.g., through pathways 36 and 40) without plastically deforming or fracturing. For example, in one embodiment, filament 44 is capable of withstanding elastic strains greater than t/r, where “t” is a cross-sectional thickness of filament 44 in the plane of curvature, and “r” is a bend radius (e.g., a bend radius in supply source 20 or 22 and/or a bend radius through pathway 36 or 40).

In one embodiment, the composition of ribbon filament 44 is substantially homogenous along length 46. Additionally, the composition of ribbon filament 44 desirably exhibits a glass transition temperature that is suitable for use in build chamber 12. Examples of suitable glass transition temperatures at atmospheric pressure for the composition of filament 44 include temperatures of about 80° C. or greater. In some embodiments, suitable glass transition temperatures include about 100° C. or greater. In additional embodiments, suitable glass transition temperatures include about 120° C. or greater.

Filament 44 also desirably exhibits low compressibility such that its axial compression doesn't cause filament 44 to be seized within a liquefier. Examples of suitable Young's modulus values for the polymeric compositions of filament 44 include modulus values of about 0.2 gigapascals (GPa) (about 30,000 pounds-per-square inch (psi)) or greater, where the Young's modulus values are measured pursuant to ASTM D638-08. In some embodiments, suitable Young's modulus range from about 1.0 GPa (about 145,000 psi) to about 5.0 GPa (about 725,000 psi). In additional embodiments, suitable Young's modulus values range from about 1.5 GPa (about 200,000 psi) to about 3.0 GPa (about 440,000 psi).

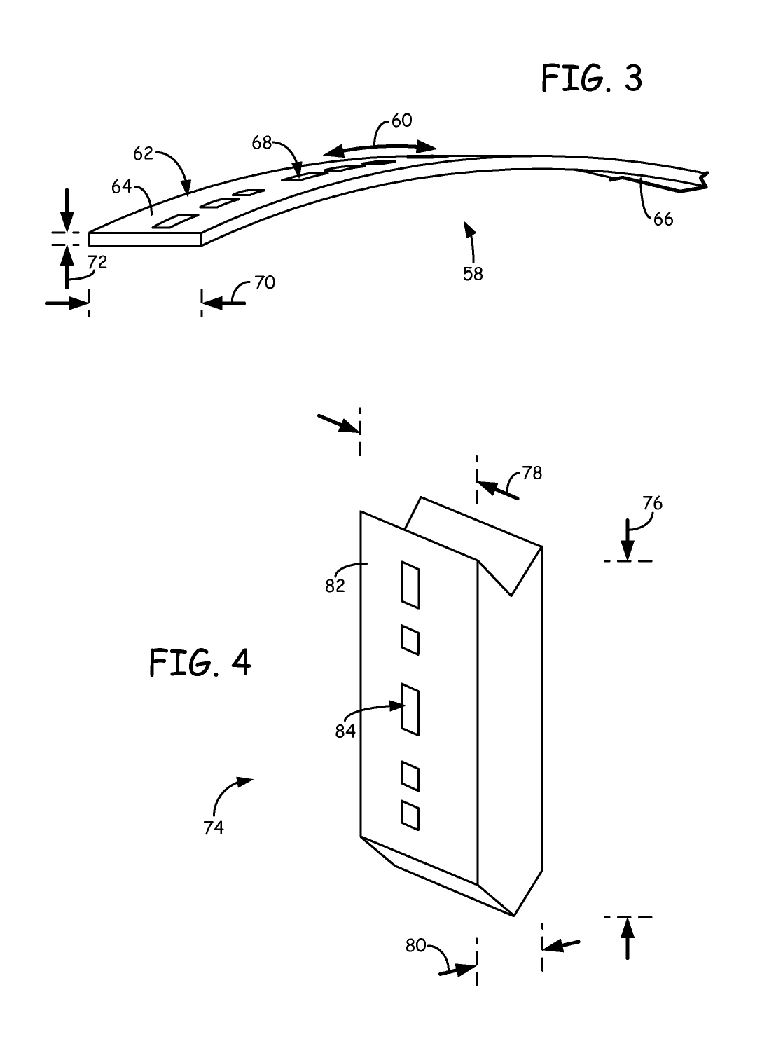

FIG. 3 illustrates a segment of filament 58, which is an additional example of a suitable marked consumable material of the present disclosure for use as a modeling material and/or a support material with system 10 (shown in FIG. 1). As shown in FIG. 3, filament 58 is a marked non-cylindrical filament having length 60, where length 60 is a continuous length that may vary depending on the amount of filament 58 remaining in supply source 20 or 22. While only a segment of filament 58 is illustrated in FIG. 3, it is understood that length 60 of filament 58 may extend for a substantial distance (e.g., greater than 25 meters).

Filament 58 also includes exterior surface 62 extending along length 60 and having major surfaces 64 and 66, which are the opposing major surfaces of filament 58. Filament 58 further includes encoded markings 68 located at major surface 64 of exterior surface 62, along at least a portion of length 60. In one embodiment, encoded markings 68 extend substantially along the entire length 60.

In the shown embodiment, encoded markings 68 are trench-based markings in exterior surface 62 (e.g., via laser ablation), as discussed above for encoded markings 50 of filament 44 (shown in FIG. 2). However, as discussed below, encoded markings 68 may alternatively be formed on filament 58 using a variety of different marking techniques (e.g., via one or more coating processes).

Encoded markings 68 may extend in a single linear path along length 60 at major surface 64, as shown. In comparison to filament 44, which has a cylindrical cross section, filament 58 is less susceptible to axial rotation due to its rectangular cross section. As such, so long as filament 58 is provided to system 10 in the proper orientation, sensor assembly 24 or 26 may read encoded markings 68 as successive portions of filament 58 pass through the given sensor assembly 24 or 26. In an alternative embodiment, encoded markings 50 may also include an additional linear path along length 60 at major surface 66, and/or along the edges of filament 58. This embodiment allows sensor assembly 24 or 26 to read encoded markings 68 regardless of the orientation of filament 58. In additional alternative embodiments, filament 58 may include additional paths of encoded markings 68 at one or both of major surfaces 64 and 66. Furthermore, one or more of the paths of encoded markings 68 may extend along length 60 in a non-linear manner (e.g., S-curves and spiral arrangements).

Encoded markings 68 may include a variety of different information, such as information relating to filament 58 and/or system 10, which may be read by sensor assembly 24 or 26 in the same manner as discussed above for encoded markings 50 of filament 44. Accordingly, suitable types of information that may be retained in encoded markings 68 include those discussed above for encoded markings 50.

Filament 58 has a cross section defined by width 70 and thickness 72, thereby defining a non-cylindrical cross section. Examples of suitable non-cylindrical filaments for filament 58 include those disclosed in Batchelder et al., U.S. Provisional Patent Application Nos. 61/247,067; 61/247,068; and 61/247,078. Filament 58 is also desirably flexible along length 60 to allow filament 58 to be retained in supply sources 20 and 22 (e.g., wound on spools) and to be fed through system 10 (e.g., through pathways 36 and 40) without plastically deforming or fracturing. For example, in one embodiment, filament 58 is capable of withstanding elastic strains greater than t/r, where “t” is a cross-sectional thickness of filament 58 in the plane of curvature, and “r” is a bend radius (e.g., a bend radius in supply source 20 or 22 and/or a bend radius through pathway 36 or 40).

Examples of suitable average dimensions for width 70 range from about 1.0 millimeter (about 0.04 inches) to about 10.2 millimeters (about 0.40 inches), with particularly suitable average widths ranging from about 2.5 millimeters (about 0.10 inches) to about 7.6 millimeters (about 0.30 inches), and with even more particularly suitable average widths ranging from about 3.0 millimeters (about 0.12 inches) to about 5.1 millimeters (about 0.20 inches).

Examples of suitable average dimensions for thickness 72 range from about 0.08 millimeters (about 0.003 inches) to about 1.5 millimeters (about 0.06 inches), with particularly suitable average thicknesses ranging from about 0.38 millimeters (about 0.015 inches) to about 1.3 millimeters (about 0.05 inches), and with even more particularly suitable average thicknesses ranging from about 0.51 millimeters (about 0.02 inches) to about 1.0 millimeter (about 0.04 inches).

Examples of suitable aspect ratios of width 70 to thickness 72 include aspect ratios greater than about 2:1, with particularly suitable aspect ratios ranging from about 2.5:1 to about 20:1, and with even more particularly suitable aspect ratios ranging from about 3:1 to about 10:1.

The dimensions and geometries of each mark of encoded markings 68 may also vary depending on the encoding scheme and the marking technique used. In the current example in which encoded markings 68 are formed as trenches in exterior surface 62 (e.g., via laser ablation), encoded markings 68 desirably have small dimensions relative to the overall dimensions of filament 58 to minimize or otherwise reduce their impact on the cross sectional area of filament 58. Additionally, as shown in the current embodiment, the trenches of encoded markings 68 have axial lengths (along length 60) that vary to provide patterns based on the encoding scheme used. In alternative embodiments one or more of the widths of the marks (along width 70) and/or the depths of the marks (along thickness 72) may additionally or alternatively be varied to provide patterns based on the encoding scheme used. Examples of suitable axial lengths, widths, and depths for each mark of encoded markings 68 include those discussed above for encoded markings 50 of filament 44.

Filament 58 may also be manufactured from a variety of extrudable modeling and support materials for respectively building 3D model 28 and support structure 30. Examples of suitable modeling and support materials include those discussed above for filament 44. Filament 58 also desirably exhibits physical properties that allow filament 58 to be used as a consumable material in system 10. In one embodiment, the composition of filament 58 is substantially homogenous along length 60. Additionally, the composition of filament 58 desirably exhibits a glass transition temperature that is suitable for use in build chamber 12. Examples of suitable glass transition temperatures at atmospheric pressure for the composition of filament 58 include those discussed above for filament 44. Filament 58 also desirably exhibits low compressibility such that its axial compression doesn't cause filament 58 to be seized within a liquefier. Examples of suitable Young's modulus values for the polymeric compositions of filament 58 include those discussed above for filament 44.

FIG. 4 illustrates slug or wafer 74, which is an additional example of a suitable marked consumable material of the present disclosure for use as a modeling material and/or a support material with system 10 (shown in FIG. 1). As shown in FIG. 4, slug 74 dimensionally includes length 76, width 78, and thickness 80. Examples of suitable designs for slug 74 include those disclosed in Batchelder et al., U.S. Pat. No. 5,764,521. Accordingly, a series of slugs 74 may be fed through pathway 36 or 40 in an end-to-end arrangement to provide slugs 74 to extrusion head 18.

Slug 74 also includes exterior surface 82 extending along length 76, and encoded markings 84 located at exterior surface 82, along at least a portion of length 76. In one embodiment, encoded markings 84 extend substantially along the entire length 86. In the shown embodiment, encoded markings 84 are trench-based markings in exterior surface 82 (e.g., via laser ablation), as discussed above for encoded markings 50 of filament 44 (shown in FIG. 2). However, as discussed below, encoded markings 84 may alternatively be written to slug 74 using a variety of different marking techniques (e.g., via one or more coating processes).

Encoded markings 84 may extend in a single linear path along length 76 at one or both major surfaces of exterior surface 82, as shown. In additional alternative embodiments, slug 74 may include additional paths of encoded markings 84 at one or both of major surfaces of exterior surface 82. Furthermore, one or more of the paths of encoded markings 84 may extend along length 76 in a non-linear manner (e.g., S-curves and spiral arrangements).

Encoded markings 84 may also include a variety of different information, such as information relating to slug 74 and/or system 10, which may be read by sensor assembly 24 or 26 in the same manner as discussed above for encoded markings 50 of filament 44. Accordingly, suitable types of information that may be retained in encoded markings 84 include those discussed above for encoded markings 50.

Examples of suitable average dimensions for length 76 range from about 25 millimeters (about 1.0 inch) to about 150 millimeters (about 6.0 inches), with particularly suitable average lengths ranging from about 38 millimeters (about 1.5 inches) to about 76 millimeters (about 3.0 inches), and with even more particularly suitable average lengths ranging from about 43 millimeters (about 1.7 inches) to about 64 millimeters (about 2.5 inches).

Examples of suitable average dimensions for width 78 range from about 10 millimeters (about 0.4 inches) to about 38 millimeters (about 1.5 inches), with particularly suitable average widths ranging from about 13 millimeters (about 0.5 inches) to about 33 millimeters (about 1.3 inches), and with even more particularly suitable average widths ranging from about 15 millimeters (about 0.6 inches) to about 25 millimeters (about 1.0 inch).

Examples of suitable average dimensions for thickness 80 range from about 1.3 millimeters (about 0.05 inches) to about 13 millimeters (about 0.5 inches), with particularly suitable average thicknesses ranging from about 2.5 millimeters (about 0.1 inches) to about 7.6 millimeters (about 0.3 inches), and with even more particularly suitable average thicknesses ranging from about 3.8 millimeters (about 0.15 inches) to about 6.4 millimeters (about 0.25 inches).

The dimensions and geometries of each mark of encoded markings 84 may also vary depending on the encoding scheme and the marking technique used. In the current example in which encoded markings 84 are formed as trenches in exterior surface 82 (e.g., via laser ablation), encoded markings 84 desirably have small dimensions relative to the overall dimensions of slug 74 to minimize or otherwise reduce their impact on the cross sectional area of slug 74. Additionally, as shown in the current embodiment, the trenches of encoded markings 84 have axial lengths (along length 76) that vary to provide patterns based on the encoding scheme used. In alternative embodiments one or more of the widths of the marks (along width 78) and/or the depths of the marks (along thickness 80) may additionally or alternatively be varied to provide patterns based on the encoding scheme used. Examples of suitable axial lengths, widths, and depths for each mark of encoded markings 84 include those discussed above for encoded markings 50 of filament 44.

Slug 74 may also be manufactured from a variety of extrudable modeling and support materials for respectively building 3D model 28 and support structure 30. Examples of suitable modeling and support materials include those discussed above for filament 44. Slug 74 also desirably exhibits physical properties that allow slug 74 to be used as a consumable material in system 10. In one embodiment, the composition of slug 74 is substantially homogenous along length 76. Additionally, the composition of slug 74 desirably exhibits a glass transition temperature that is suitable for use in build chamber 12. Examples of suitable glass transition temperatures at atmospheric pressure for the composition of slug 74 include those discussed above for filament 44. Slug 74 also desirably exhibits low compressibility such that its axial compression doesn't cause slug 74 to be seized within a liquefier. Examples of suitable Young's modulus values for the polymeric compositions of slug 74 include those discussed above for filament 44.

In addition to the above-discussed marked consumable material geometries, the marked consumable materials of the present disclosure include a variety of geometries, such as pellet geometries, irregular geometries, and the like. For example, the marked consumable materials may be provided as pellets with one or more linear encodings formed on the exterior surfaces of the pellets as discussed above for filament 44, filament 58, and slug 74. Examples of suitable pellet geometries include pellets having length-to-cross section (e.g., length-to-diameter) ratios ranging from about 1:1 to about 10:1. In some embodiments, suitable length-to-cross section ratios range from about 2:1 to about 5:1. The pellets may also include random fractured portions, such as random fractured ends.

Examples of suitable average cross sectional areas for the pellets range from about 0.2 square-millimeters to about 15 square-millimeters, with particular suitable average cross sectional areas ranging from about 0.75 square-millimeters to about 5 square millimeters. In embodiments in which the pellets have somewhat cylindrical cross sections, examples of suitable average diameters range from about 0.5 millimeters to about 4 millimeters, with particularly suitable average diameters ranging from about 1 millimeter to about 2 millimeters. Examples of suitable average lengths for the pellets range from about 1 millimeter to about 20 millimeters, with particularly suitable average lengths ranging from about 2 millimeters to about 10 millimeters.

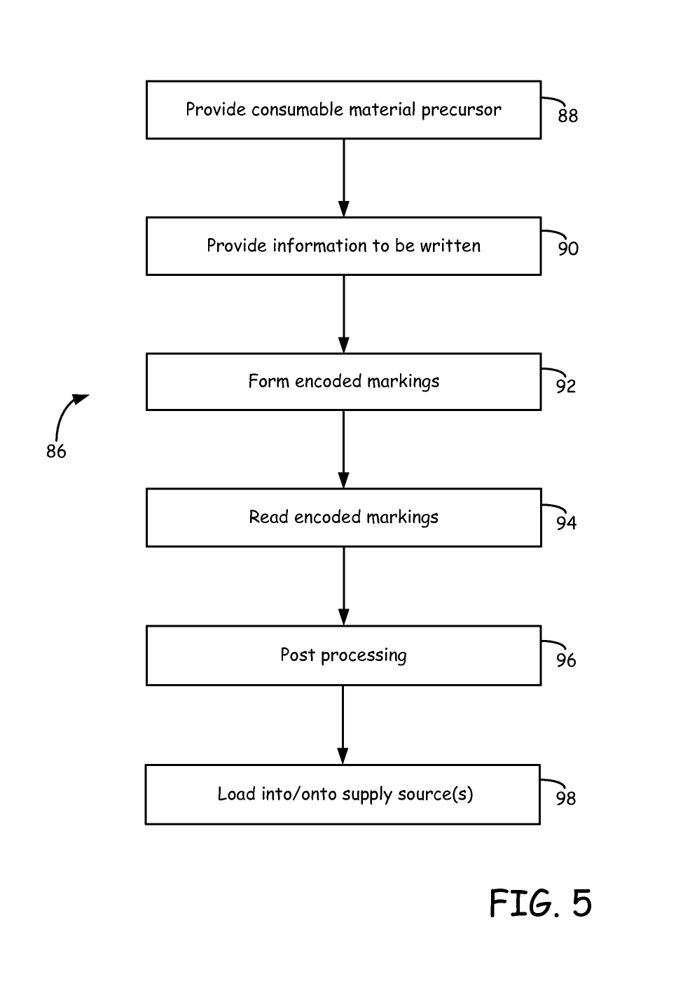

FIG. 5 is a flow diagram of method 86 for manufacturing the marked consumable materials of the present disclosure, such as filament 44 (shown in FIG. 2), filament 58 (shown in FIG. 3), and slug 74 (shown in FIG. 4). Method 58 includes steps 88-98, and initially involves providing a consumable material precursor, which is the consumable material in an unmarked state (step 88). For example, the precursor may be provided as a prefabricated material (e.g., filament or slug) in a solid state (e.g., retained on a supply source). Alternatively, the precursor may be provided by extruding the modeling or support material to form the precursor.

Examples of suitable techniques for forming the precursor for filament 44 include those disclosed in Comb. et al., U.S. Pat. Nos. 6,866,807 and 7,122,246. Examples of suitable techniques for forming the precursor for filament 58 include those disclosed in Batchelder et al., U.S. Provisional Patent Application Nos. 61/247,067. Examples of suitable techniques for forming the precursor for slug 74 include those disclosed in Batchelder et al., U.S. Pat. No. 5,764,521. Additional examples of suitable techniques for forming the precursor with topographical surface patterns configured to engage with a filament drive mechanism of system 10 include those disclosed in Batchelder et al., U.S. Provisional Patent Application No. 61/247,078.

The information to be written to the precursor as encoded markings may also be provided (step 90). For example, the information may be retained in one or more computer systems prior to being written to the precursor. In one embodiment in which the information includes physical properties of the precursor, such as the local filament cross-sections (e.g., diameters and root-mean-square variations), this information may be obtained by measuring the precursor and storing the measurements in one or more computer systems prior to being written to the precursor as encoded markings. For example, after the precursor of filament 44 is extruded and solidified, the diameters of successive portions of filament 44 may be measured and stored for subsequent writing as at least a portion of encoded markings 50.

The encoded markings (e.g., encoded markings 50, 68, and 84) may then be formed at the exterior surface while the precursor is at least partially solidified (step 92). In one embodiment, the encoded markings are formed at the exterior surface while the precursor is fully solidified. The pattern of the encoded markings may be based on the information being written, the encoding scheme used, and the device used to mark the precursor. A variety of encoding schemes may be used, where the encoding scheme desirably allows the encoded markings to be written to the precursor without substantially reducing line speeds. Examples of suitable average line speeds for manufacturing the marked consumable materials include line speeds up to about 20 meters/second (about 750 inches/second), with particularly suitable average line speeds ranging from about 1.3 meters/second (about 50 inches/second) to about 5 meters/second (about 200 inches/second). Additionally, the encoding scheme also desirably allows the encoded markings to be read by sensor assembly 24 or 26 in system 10 without substantially affecting the drive rate of the marked consumable material to extrusion head 18.

As discussed above, encoded markings 50, 68, and 84 may be formed as trench-based markings in the precursor. The trenches may be formed within the exterior surface of the precursor using a variety of techniques, such as laser ablation, physical imprinting, chemical etching (e.g., with masking), and combinations thereof. Due to the small dimensions and materials of the precursor, the particular technique used to form the trenches of the encoded markings is desirably selected to reduce the risk of significantly damaging or cracking the precursor while forming the trenches. As discussed below, the edges of the trench marks are suitable regions for scattering light in a darkfield illumination, which may allow an optical sensor assembly to read the encoded markings based on the patterns of the scattered light.

A suitable laser ablation technique for forming the encoded markings as trenches in the exterior surface of the precursor may be performed with an ultraviolet laser, such as an excimer laser. An excimer laser may remove material from the exterior surface of the precursor without significant damage or cracking to the underlying material of the precursor. Furthermore, excimer light may be strongly absorbed such that the surface material may be converted to vapor, leaving a trench without micro-cracks or residual ash. This embodiment is also beneficial for forming the encoded markings in a continuous manner, in which successive portions of the precursor may be exposed to the excimer laser.

Alternatively, the encoded markings may be formed with a variety of different processes. In one embodiment, the encoded markings may be formed with one or more coating processes, which may form the encoded markings on the exterior surface of the precursor as coatings that may be optically detected. For example, the coatings may be formed with a jetting, deposition, or evaporation process, where the coating is desirably formed with a material that is not readily visible to the naked eye but may be detected using a non-visible wavelength (e.g., ultraviolet-activated materials). In these embodiments, the sensor assembly (e.g., sensor assemblies 24 and 26) may emit light in one or more non-visible wavelengths and detect the light emitted from the activated materials of the encoded markings. These embodiments are beneficial for reducing the impact of the encoded markings on the colors of the modeling and support materials.

In additional alternative embodiments, the encoded markings may be formed by one or more mechanical impression processes, such as by mechanically impressing the pattern into the surface, such as with an agile stylus, rotating die, a recycling belt, and the like. The exterior surface may also be machined, skived, ground, polished, and the like. Furthermore, the encoded markings may be produced by one or more surface property modification processes, such as by modifying the surface properties of the precursor material. For example, the degree of cross linking of the precursor material may be locally modified by ultraviolet light to varying the index of refraction. Ion implantation can similarly modify the local complex index.

After a particular segment of the precursor is marked with the encoded markings to form the marked consumable material, the recently formed encoded markings may optionally be read with a sensor assembly to ensure that the information in the encoded markings is accurate (step 94). If the information is determined to be accurate, the marked consumable material may optionally undergo one or more post-processing operations (step 96), and then may be loaded into or onto a supply source (e.g., supply sources 20 and 22) for subsequent use in a direct digital manufacturing system (e.g., system 10) (step 98). In alternative embodiments, steps 94, 96, and 98 may be performed in different orders and/or one or both of steps 94 and 96 may be omitted.

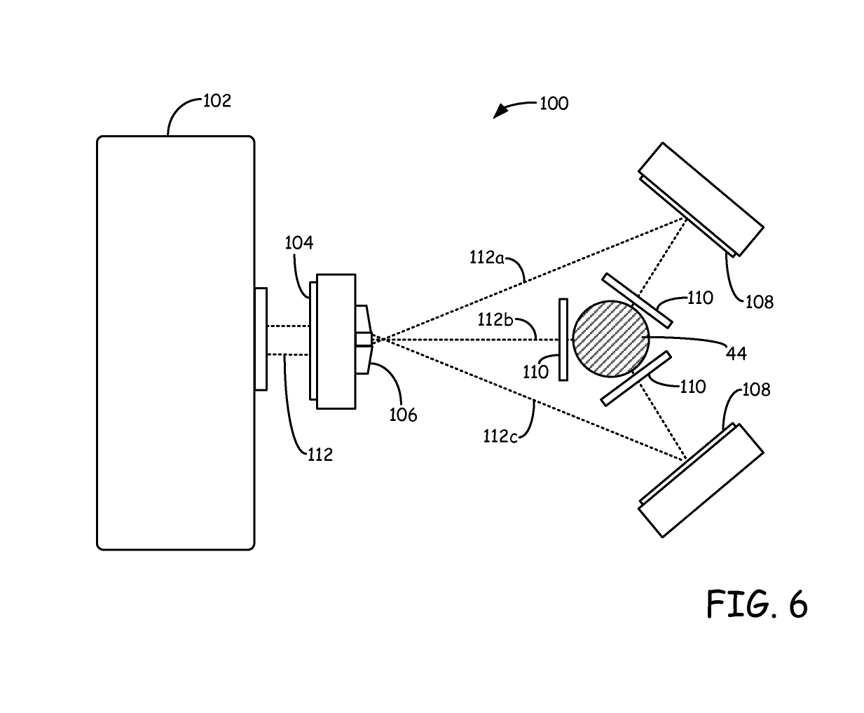

FIG. 6 is a schematic illustration of marking system 100, which is an example of a suitable laser marking system for forming encoded markings in a consumable material precursor, pursuant to step 92 of method 86 (shown in FIG. 5). The following discussion of marking system 100 is made with reference to filament 44 (shown in FIG. 2) with the understanding that marking system 100 may also be modified for forming encoded markings for a variety of marked consumable materials of the present disclosure (e.g., filament 58 shown in FIG. 3, and slug 74 shown in FIG. 4).

As shown in FIG. 6, marking system 100 is a laser ablation system (e.g., an excimer laser ablation system) that includes laser source 102, encoder mask 104, beam splitter 106, reflectors 108, and slot apertures 110. Laser source 102 is a laser emission source (e.g., an excimer laser source) for emitting laser beam 112 toward dielectric mask 104. In one embodiment, laser source 102 is configured to emit laser beam 112 having an ultraviolet-radiation wavelength. In another embodiment, the wavelength for laser beam 112 ranges from about 100 nanometers to about 400 nanometers. In yet another embodiment, the wavelength for laser beam 112 ranges from about 150 nanometers to about 300 nanometers.

Laser source 102 also desirably emits laser beam 112 with an energy level that is sufficient to form the trenches of encoded markings 50 in the material of the precursor for filament 44, while also desirably being low enough to reduce the risk of significantly damaging or cracking the precursor while forming the trenches. Examples of suitable energy levels per pulse of laser beam 112, based on a pulse length of about 8 nanoseconds, range from about 4 millijoules to about 20 millijoules, with particularly suitable energy levels ranging from about 8 millijoules to about 15 millijoules.

Laser source 102 also desirably emits pulses of laser beam 112 with sufficient frequencies to form trenches of encoded markings 50 along successive portions of the precursor of filament 44 while maintaining a suitable line speed for filament 44. Examples of suitable pulse frequencies for laser beam 112 range from about 500 hertz to about 1,500 hertz.

Encoder mask 104 is a mask configured to selectively form encoded marks 50 in filament 44 with laser beam 112 based on an encoding scheme. Examples of suitable encoder masks for encoder mask 104 include fixed and rotary-disk dielectric masks, such as chrome-on-fluoride masks (e.g., glass and quartz-based masks), which may contain coded patterns. For example, a rotary disk mask may contain radially coded patterns, where the timing of the pulse of laser beam 112 may select which encoded pattern is illuminated for imprinting onto filament 44.

Beam splitter 106 is configured to split laser beam 112 into separate laser beams (referred to as laser beams 112a, 112b, and 112c) for forming encoded patterns 50a, 50b, and 50c in filament 44. Reflectors 108 are reflective surfaces (e.g., dielectric mirrors) configured to reflect laser beams 112a and 112c back toward filament 44. Slot apertures 110 are spaced around filament 44 and are configured to limit the radial dimensions of encoded patterns 50a, 50b, and 50c.

During operation, the precursor of filament 44 may be fed through slot apertures 110, as shown. The information to be written to the precursor may then be encoded by a computer system (not shown) in signal communication with system 100. Based on the encoding scheme used, the computer system may direct laser source 102 pulse laser beam 112 toward encoder mask 104. The encoded pattern in encoder mask 104 may vary the patterns of laser beam 112 that pass through encoder mask 104 to beam splitter 106. Beam splitter 106 splits the portion of laser beam 112 that passed through encoder mask 104 into laser beams 112a, 112b, and 112c. Laser beams 112a, 112b, and 112c may then be directed to exterior surface 48 of the precursor of filament 44 to desirably form trenches in the precursor based on the laser beam pattern.

For example, an energy pulse of about 12 millijoules may form a trench by removing about 1.2 square millimeters (about 1,900 square mils) of a polymer (e.g., ABS) to depth of about 2.5 micrometers (about 0.1 mils). If laser beam 112 is used to form trenches that are about 0.2 millimeters (about 8 mils) wide (e.g., width 56) and about 2.5 millimeters (about 100 mils) long (e.g., length 54) with a pulse frequency of about 1,000 hertz, encoded markings 50 may be formed in the precursor at a line speed greater than about 2.5 meters/second (about 100 inches/second). As such, system 100 may be used in a continuous process with the extrusion and formation of the precursor of filament 44. The marking process may continue as successive portions of the precursor pass through system 100, thereby forming successive trenches of encoded markings 50 along length 46. The resulting filament 44 may then subjected to one or more additional steps of method 86 (e.g., steps 94, 96, and 98), as discussed above.

As discussed above, the marked consumable materials of the present disclosure allow information to be recorded in the consumable materials themselves. The encoded markings may contain a variety of information relating to the marked consumable materials and/or to the operations of the direct digital manufacturing systems (e.g., system 10). Additionally, the sensor assemblies (e.g., sensor assemblies 24 and 26) are configured to read the encoded markings from successive portions of the marked consumable materials as the marked consumable materials are fed to the direct digital manufacturing systems. This allows the direct digital manufacturing systems to use the information in the encoded markings for a variety of different purposes, such as for building 3D models and/or support structures.

Although the present disclosure has been described with reference to preferred embodiments, workers skilled in the art will recognize that changes may be made in form and detail without departing from the spirit and scope of the disclosure.

1. A marked consumable material for use in a direct digital manufacturing system, the marked consumable material comprising an exterior surface having encoded markings that are configured to be read by at least one sensor of the direct digital manufacturing system, wherein the marked consumable material is configured to be consumed in the direct digital manufacturing system to build at least a portion of a three-dimensional model.

2. The marked consumable material of claim 1, wherein the marked consumable material comprises a filament having a length, and wherein the encoded markings extend along at least a portion of the length of the filament.

3. The marked consumable material of claim 2, wherein the encoded markings comprise a plurality of paths, and wherein at least one of the plurality of paths extends along at least a portion of the length of the filament.

4. The marked consumable material of claim 2, wherein the filament comprises a substantially cylindrical geometry having an average diameter ranging from about 0.8 millimeters to about 2.5 millimeters.

5. The marked consumable material of claim 2, wherein the filament has a cross section with a width and thickness, wherein the width of the cross section ranges from about 1.0 millimeter to about 10.2 millimeters, and wherein the thickness of the cross section ranges from about 0.08 millimeters to about 1.5 millimeters.

6. The marked consumable material of claim 1, wherein the encoded markings comprise a plurality of trenches extending within an exterior surface of the consumable material.

7. The marked consumable material of claim 6, wherein the plurality of trenches have an average depth from the exterior surface ranging from about 1.3 micrometers to about 51 micrometers.

8. The marked consumable material of claim 1, wherein the encoded markings comprise one or more types of encoded information selected from the group consisting of local consumable material cross-sections, consumable material extrusion parameters, amount of the marked consumable material remaining, measurements of local consumable material fingerprint characteristics, material types, material compositions, material colors, manufacturing information for the marked consumable material, product codes, material origin information, software and firmware updates for the direct digital manufacturing system, media-based information, and combinations thereof.

9. A method of manufacturing a marked consumable material for use in a direct digital manufacturing system, the method comprising:
providing a consumable material precursor comprising an exterior surface, wherein the consumable material precursor is formed from an extrudable material; and
forming encoded markings at the exterior surface of the consumable material precursor, wherein the encoded markings are configured to be read by at least one sensor in the direct digital manufacturing system, and wherein the marked consumable material is configured to be consumed in the direct digital manufacturing system to build at least a portion of a three-dimensional model.

10. The method of claim 9, wherein providing the consumable material precursor comprises forming the consumable material precursor from the extrudable material.

11. The method of claim 9, wherein the consumable material precursor comprises a filament precursor having a length, and wherein forming the encoded markings comprises forming the encoded markings at the exterior surface along at least a portion of the length of the filament precursor.

12. The method of claim 9, wherein forming the encoded markings at the exterior surface comprises forming the encoded markings as a plurality of trenches within the exterior surface.

13. The method of claim 12, wherein forming the encoded markings as the plurality of trenches within the exterior surface comprises a laser ablation process.

14. The method of claim 9, and further comprising reading the formed encoded markings prior to loading the marked consumable material to a supply source.

15. The method of claim 9, wherein forming the encoded markings at the exterior surface comprises performing at least one marking technique selected from the group consisting of laser ablation processes, coating processes, mechanical impression processes, surface property modification processes, and combinations thereof.

16. A method for building a three-dimensional model with a direct digital manufacturing system, the method comprising:
feeding a marked consumable material to the direct digital manufacturing system, the marked consumable material comprising an exterior surface having encoded markings;
reading at least a portion of the encoded markings while feeding the marked consumable material to the direct digital manufacturing system;
melting the marked consumable material to at least an extrudable state in the direct digital manufacturing system; and
depositing the melted material from a deposition head of the direct digital manufacturing system to form the three-dimensional model in a layer-by-layer manner.

17. The method of claim 16, wherein reading the portion of the encoded markings comprises optically detecting the encoded markings with an optical sensor assembly.

18. The method of claim 16, and further comprising transmitting signals relating to the read encoded markings to a controller of the direct digital manufacturing system.

19. The method of claim 16, and further comprising adjusting at least one property of the direct digital manufacturing system based on the read encoded markings.

20. The method of claim 16, wherein reading the portion of the encoded markings is performed at one or more locations between and including a supply source of the marked consumable material and the deposition head of the direct digital manufacturing system.
